(19) United States
(12) Patent Application Publication
(10) Pub. No.: US 2010/0181591 A1
(43) Pub. Date: Jul. 22, 2010

(54) LED ILLUMINATION DEVICE USING DIFFRACTION MEMBER

(75) Inventor: Fumio Suzuki, Kyoto-shi (JP)

Correspondence Address: ALLEMAN HALL MCCOY RUSSELL & TUTTLE LLP, 806 SW BROADWAY, SUITE 600, PORTLAND, OR, 97205-3335, US

(73) Assignee: ABEL SYSTEMS INCORPORATION, Kyoto-shi, Kyoto (JP)

(21) Appl. No.: 12/667,026

(22) PCT Filed: Jul. 9, 2007
(86) PCT No.: PCT/JP2007/063694

§ 371 Date: Dec. 28, 2009

(30) Foreign Application Priority Data
Jun. 29, 2007 (JP) 2007-171911

(51) Int. Cl. H01L 33/00

(52) U.S. Cl. 257/98; 257/E33.058; 257/E33.061; 257/E33.067

(57) ABSTRACT

An object of this invention is to provide an LED illumination device that can substitute for a fluorescent light and obtain uniform light with high efficiency. The LED illumination device comprises an LED with a thin-plate-shaped semiconductor element body transmitting the light generated in a PN junction area in a thickness direction and emits it from the surface, a surface electrode that covers the surface of the semiconductor element body, and columnar dielectric antennas that penetrate the surface electrode in the thickness direction and that condense the light transmitted in a body of the semiconductor element and emit it outside, a diffraction member that is arranged on a luminous surface side of the LED and that diffracts and disperses the light emitted by the LED, and a diffusion member that is arranged outside the diffraction member and that diffuses the light dispersed by the diffraction member and emits it outside.

### FIELD OF THE ART

This invention relates to an LED illumination device using a high efficiency LED that can produce plane emission.

### BACKGROUND ART

Since an LED has a longer operating life and its light intensity is more stable compared to a fluorescent light or an incandescent lamp, no time is required for starting-up the LED and there is no problem of discarding the LED. Recently a high power LED was developed in addition to the LED that emits blue light or ultraviolet light so that applications of LEDs are expanding not only to include conventional indicators but also to include general illumination devices.

However, in view of a total light intensity or an illumination intensity, even though a light intensity per unit illuminating area is increasing, the LED is still behind the fluorescent light. In order to obtain a light intensity comparable to that of the fluorescent light in total, a lot of LEDs are required and a heat release value also gets very big, which requires a heat dissipating member as shown in the patent documents 1 and 2.

One of these causes is that the conventional LED is low in luminous efficiency and small in luminous area. As is known, the LED has an arrangement that a PN junction layer emits light by applying a forward voltage to a semiconductor element having the PN junction layer, and the light generated on the PN junction layer is emitted from the surface of the semiconductor element after the generated light passes the semiconductor element in its thickness direction. However, since an electrode is attached to the surface of the semiconductor element and the electrode blocks the light, it impedes the improvement of the efficiency of transmitting the light outside and impedes increasing the light intensity by enlarging the area. In spite of this, if the area of the electrode is made small, more than a certain level in comparison with the area of the semiconductor element, it becomes impossible to provide a uniform electric field to the entire semiconductor element, thereby declining the luminescent amount. As a result, even though the area of the semiconductor element is enlarged in order to obtain a large amount of the light intensity, there is no other choice but to enlarge the area of the electrode in order to enable the plane emission, which makes it difficult to take a large amount of the light intensity outside because of the light shielding effect. In addition, in view of the problem it is conceived that a transparent electrode such as an ITO is used, however, since a specific resistance of the transparent electrode is bigger in comparison with that of a metal electrode, a loss is generated at the metal electrode so that the luminous efficiency is lowered.

Patent document 1: Japan patent laid-open number 2005-166578

Patent document 2: Japan patent laid-open number 2007-109504

Patent document 3: Japan patent laid-open number 2003-078167

### DISCLOSURE OF THE INVENTION

### Problems to be Solved by the Invention

As mentioned, it is impossible for the conventional LED to increase the luminous efficiency in a given electric power to a value more than a certain value. In addition, it is also difficult to emit the light in a large area by means of a single element, namely, it is difficult to emit the light having a large amount of the light intensity by means of a single element.

Then, as shown in the patent document 3, an inventor of this invention has focused attention on the light being an electromagnetic wave and has developed an innovative LED wherein the multiple microscopic dielectric antennas that condense and transmit the light by means of the antenna effect to the light are arranged to penetrate an electrode. With this LED, it is possible to take the light outside with high efficiency by enabling an ideal plane emission.

The present claimed invention intends to provide an LED illumination device that can substitute for an existing illumination device such as a fluorescent lamp by making use of the LED that can take the light outside with high efficiency by enabling the ideal plane emission with a single element. A concrete object of this invention is to obtain the uniform light and to make it possible to be preferably tailored to various lighting purposes including general lighting.

### Means to Solve the Problems

In order to attain these objects, the LED illumination device in accordance with this invention is characterized by comprising the following (1)˜(3). (1) An LED equipped with a thin-plate-shaped semiconductor element body that transmits the light generated in a PN junction area in a thickness direction and that emits the light from its surface, a surface electrode that is arranged to cover the surface of the semiconductor element body, and a plurality of columnar dielectric antennas that penetrate the surface electrode in the thickness direction and that condense the light transmitted in the semiconductor element body and emit it outside. (2) A diffraction member that is arranged on a luminous surface side of the LED and that diffracts and disperses the light emitted by the LED. (3) A diffusion member that is arranged outside the diffraction member and that diffuses the light dispersed by the diffraction member and emits it outside.

In accordance with this arrangement, since the light irradiated from the LED is once dispersed into the multiple point light sources or the line light source by the diffraction member and the dispersed light is further diffused by the diffusion member and then irradiated outside, it is possible to obtain more uniform light compared to a case where the light is diffused by the light diffusion member alone. In addition, in the case of obtaining the light having the same uniform degree, since it is possible for the LED illumination device having the light diffraction sheet to lessen the light diffusing degree at the light diffusion member compared to the LED illumination device having the light diffusion member alone, a loss of luminous intensity at the light diffusion member can be reduced, thereby improving the efficiency as a whole.

Furthermore, since a uniform electric field can be provided to the semiconductor element body of the LED by the surface electrode, it is possible to easily obtain a large amount of light intensity by enabling ideal plane emission of the semiconductor element body. Meanwhile, since a plurality of the dielectric antennas are arranged to penetrate the surface electrode, the light being an electromagnetic wave is condensed into the dielectric antennas and emitted outside, which makes it possible to largely reduce a shading effect by the surface electrode. More specifically, it is possible to conduct the ideal plane emission and to bring the generated light having a large amount of the light intensity to outside with high efficiency by making use of the dielectric antenna and the efficiency can be improved more than twice as much as that of a conventional illumination device.

As a result of this, with this invention, it is possible not only to secure a light intensity necessary for a general illumination device, but also to reduce generation of heat because of the high efficiency. In addition, a freedom degree in designing a shape or a material of the diffraction member or the diffusion member can be greatly enlarged such that resin having a small heat resistance can be used for the diffraction member or the diffusion member, thereby enabling provision of an optimal illumination device appropriate for various purposes.

As a concrete example for realizing a lengthy illumination device that can substitute for a fluorescent light, it is preferable that the diffusion member is a lengthy member that is made of resin having translucency and that produces a light diffusing action inside or on its surface, and the LED is in a shape of a straight belt and is arranged next to the diffusion member or housed inside of the diffusion member with its longitudinal direction coincided with a longitudinal direction of the diffusion member.

In order to arrange the diffraction member between the LED and the diffusion member without imposing a burden on manufacturing, it is preferable that the diffraction member is a light transmission type diffraction sheet that diffracts and disperses the light while transmitting the light, and the light transmission type diffraction sheet is attached to a surface, which faces the luminous surface of the LED, of the diffusion member.

In order to introduce the light from the LED into the diffraction member and the diffusion member without a loss, it is preferable that the diffusion member is provided with a groove or a through bore extending toward a longitudinal direction and the LED is housed in the groove or the through bore and the light transmission type diffraction sheet is attached to a portion facing the luminous surface of the LED as being a bottom surface of the groove or an inner surface of the through bore.

As a concrete embodiment of the diffusion member represented, light scattering particles are diffused inside of a body of the diffusion member made of a transparent resin, or micro concavities and convexities are arranged on a surface of the body of the diffusion member made of a transparent resin.

In order to increase the variation of the luminescent color by making use of the diffusion member with ease, it is preferable that a fluorescent material is applied to a surface of the diffusion member or mixed into an inside of the diffusion member.

### EFFECT OF THE INVENTION

In accordance with this invention having the above arrangement, since the diffraction member is arranged between the LED and the diffusion member, it is possible to obtain more uniform light compared to a case where the light is diffused by the light diffusion material alone. In addition, in the case of obtaining the light having the same uniform degree, since it is possible for the LED illumination device having the light diffraction sheet to lessen the light diffusing degree at the light diffusion member compared to the LED illumination device having the light diffusion member alone, a loss of luminous intensity at the light diffusion member can be reduced, thereby improving the efficiency as a whole.

Furthermore, since it is possible to conduct the ideal plane emission and to bring a large amount of the light intensity of the generated light to outside with high efficiency by making use of the dielectric antennas, it is possible not only to secure a light intensity necessary for a general illumination device but also to reduce the generation of heat because of the high efficiency. As a result, a resin having a small heat resistance can be used for the diffraction member or the diffusion member, a freedom degree in designing a shape or a material of the diffraction member or the diffusion member can be greatly enlarged, which makes it possible to provide the most appropriate illumination device appropriate for various purposes.

### BRIEF DESCRIPTION OF THE DRAWINGS

FIG. 1 is a general view showing an internal structure of an LED illumination device using a diffraction member in accordance with one embodiment of this invention.

FIG. 2 is a pattern cross-sectional view of the LED illumination device using the diffraction member in accordance with this embodiment.

FIG. 3 is a pattern cross-sectional view of a plane emission LED in accordance with this embodiment.

FIG. 4 is a pattern perspective view of the plane emission LED in accordance with this embodiment.

FIG. 5 is a pattern cross-sectional view of a plane emission LED in accordance with another embodiment of this invention.

FIG. 6 is a pattern perspective view of a light transmission type diffraction sheet in accordance with this embodiment.

FIG. 7 is a pattern perspective view of an LED illumination device using a diffraction member in accordance with a further different embodiment of this invention.

FIG. 8 is a pattern cross-sectional view of an LED illumination device using a diffraction member in accordance with a further different embodiment of this invention.

### BEST MODES OF EMBODYING THE INVENTION

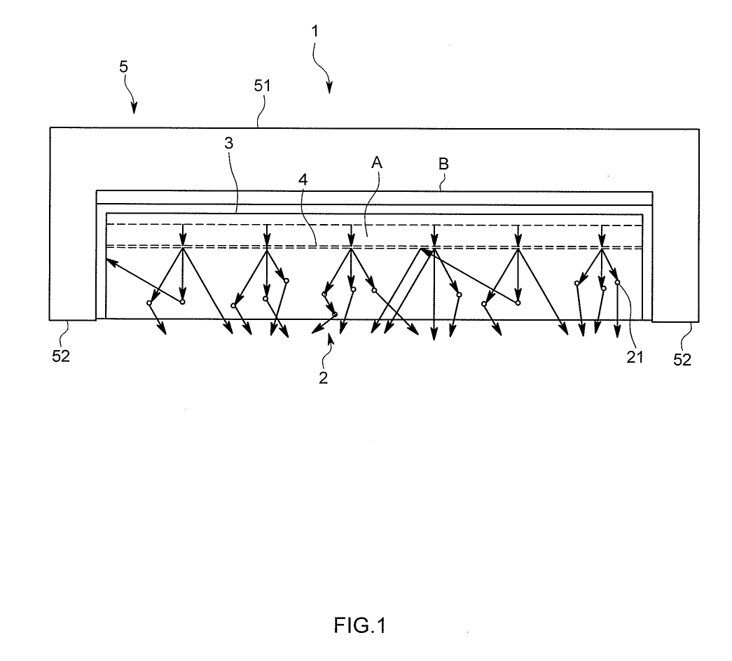

Embodiments of this invention will be explained with reference to FIG. 1 through FIG. 8.

An LED illumination device 1 in accordance with this embodiment is used for general lighting such as a room lighting instead of, for example, a fluorescent lamp, and comprises, as shown in FIG. 1, a diffusion member 2, an LED 3 mounted on the diffusion member 2, a light diffraction sheet 4 mounted on the diffusion member 2, and a holding body 5 that holds the diffusion member 2, the LED 3 and the light diffraction sheet 4.

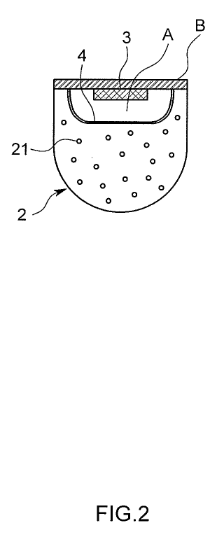

The diffusion member 2 is transparent and made of resin and contains light scattering particles 21 to diffuse the light inside. A shape of the diffusion member 2 is, for example, a column whose cross-section is generally a half circle as shown in FIG. 1 and FIG. 2. In this embodiment, a groove (A) is arranged to extend in a longitudinal direction at a string side of the generally half circle in the cross sectional view. Furthermore, a board (B) is arranged to cover the groove (A).

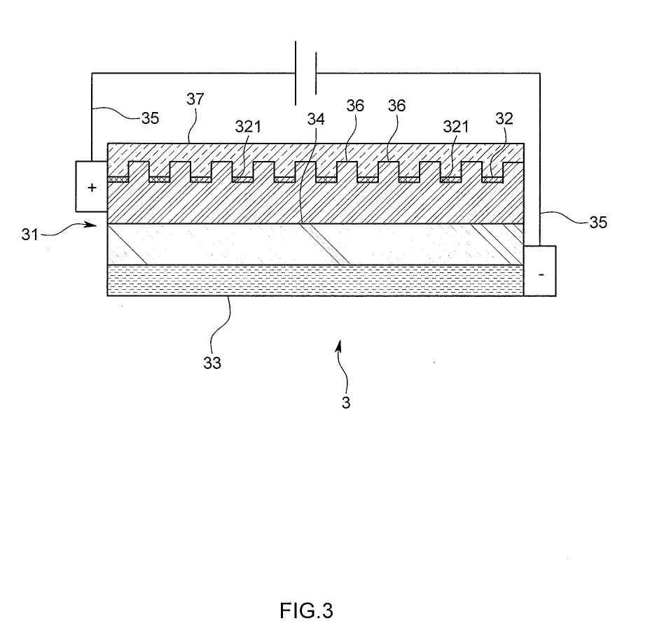

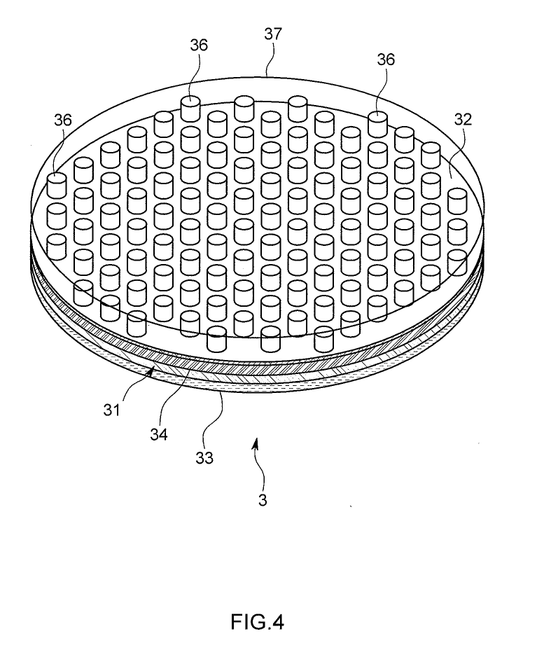

The LED 3 is, as shown in FIG. 1, in a shape of a straight belt and of a plane emission type that irradiates white light from a luminous surface by making use of a surface of one of the surface plate parts as the luminous surface. More specifically, the LED 3 comprises, as shown in FIG. 3 and FIG. 4, a semiconductor element body 31 in a thin plate shape having a PN junction structure, a surface electrode 32 arranged to generally cover a front surface of the semiconductor element body 31, and a reflecting plate also serving as a back surface electrode 33 arranged to generally cover a back surface of the semiconductor element body 31, and emits the light from a PN junction area 34 toward a direction of the thickness. A lead wire 35 for supplying electric power is connected to a peripheral part of the semiconductor element body 31. In addition, inside of the groove (A), the LED 3 is attached to the board (B) with its longitudinal direction coincided with a longitudinal direction of the diffusion member 2 and with its luminous surface facing a bottom surface of the groove (A), and emits the light inside of the diffusion member 2.

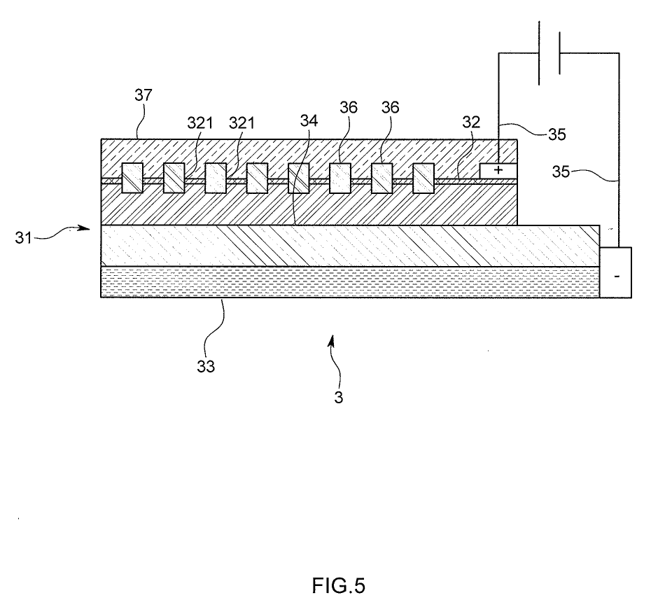

As shown in FIG. 3 and FIG. 4, a plurality of through bores 321 are formed in the thickness direction at a certain pitch on the surface electrode 32. At each through bore 321 arranged is a dielectric antenna 36 having a size so as to collect and transmit the light emitted from the semiconductor body 31. In order to effectively produce the function as the dielectric antenna 36 for the light, it is necessary for the dielectric antenna 36 to be of a size that both a height and a width (a diameter) are about from a fraction of the wavelength of the light to dozens of the wavelength of the light. More preferably, the size of the dielectric antenna 36 is about from one third to triple of the wavelength of the light. In addition, a shape of the dielectric antenna 36 is a cylinder in FIG. 3 and FIG. 4, however, it may be a polygonal column or an elliptic cylinder. Furthermore, the dielectric antenna 36 may be integrally formed with the semiconductor element body 31 or may be made of a member whose dielectric constant is different, as shown in FIG. 5.

Furthermore, in this embodiment, as shown in FIG. 3, a fluorescent resin layer 37 such as YAG phosphor is arranged further outside of the surface electrode 32. With this arrangement, the light from the semiconductor element body 31 and the fluorescence from the fluorescent resin layer 37 are mixed so that several colors are mixed and then the white light is irradiated outside as mentioned.

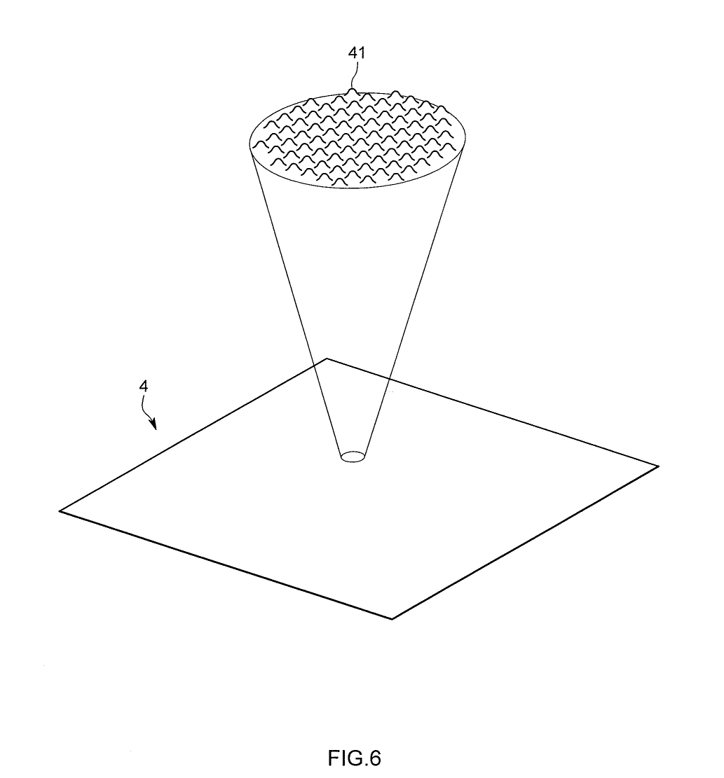

The light diffraction sheet 4 is, as shown in FIG. 6, provided with micro-projections 41 regularly on a film that transmits and inflects the light. It is preferable that an interval between each micro-projection 41 is from 30 nm to 100 μm. In addition, an interval between each micro-projection 41 may differ for every group such that an interval between micro-projections 41 for a certain line is 30 nm and an interval between micro-projections 41 for another line is 100 nm. The light entering the transparent light diffraction sheet 4 diffracts on the regularly arranged micro-projections 41, and then interferes each other so as to be a point light source or a line light source and then the light is dispersed and exits without almost any loss of the light intensity. In addition, the light diffraction sheet 4 is attached to the bottom surface of the groove (A) to face the luminous surface of the LED 3.

The holding member 5 comprises, as shown in FIG. 1, a hollow lengthy body 51 and a pair of arms 52 elongating at a right angle from each end part of the body 51. The holding member 5 detachably supports the light diffusion member 2, the LED 3 and the light diffraction sheet 4 by connecting a connector, not shown in drawings, arranged on each arm 52 with a connector, not shown in drawings, arranged at an end part of the exterior casing 2. The connector on the holding member 5 is connected to a rectifying circuit, not shown in drawings, incorporated in the body 51 and the connector of the diffusion member 2 is connected to the LED 3 so that the LED 3 is supplied with electric power and emits light by mounting the diffusion member 2, the LED 3 and the light diffraction sheet 4 on the holding member 5.

Next, an operation of the LED illumination device 1 having the above-mentioned arrangement will be briefly explained.

If the LED 3 emits light at a time when the electric power is supplied, as shown in FIG. 1, the light emitted from each LED 3 is dispersed into multiple point light sources or a line light source by means of the light diffraction sheet 4 and then the dispersed light is diffused by the light scattering particles 21 inside of the diffusion member 2. Then an outer surface part of the diffusion member 2 emits light uniformly.

In accordance with the LED illumination device 1 having the above-mentioned arrangement, since the light irradiated from the LED 3 is dispersed into the multiple point light sources or the line light source without almost any loss of the light intensity by means of the light diffraction sheet 4, and the dispersed light is further diffused by the light scattering particles 21 and then irradiated outside, it is possible to obtain more uniform light compared to a case where the light is diffused by the light scattering particles 21 alone. In addition, in the case of obtaining the light having the same uniform degree, since it is possible for the LED illumination device 1 having the light diffraction sheet 4 to lessen the light diffusing degree at the light scattering particles 21 compared to the LED illumination device having the light scattering particles 21 alone, a loss of luminous intensity at the light scattering particles 21 can be reduced, thereby improving the efficiency as a whole.

In accordance with the LED illumination device 1 having the above-mentioned arrangement, since a uniform electric field can be provided to the semiconductor element body 31 of the LED 3 by the surface electrode 32, it is possible to easily obtain a large amount of the light intensity by enabling ideal plane emission of the semiconductor element body 31. Meanwhile, since a plurality of dielectric antennas 36 are arranged to penetrate the surface electrode 32, the light being an electromagnetic wave is condensed and emitted outside, thereby enabling a large reduction of a shading effect by the surface electrode 32. More specifically, since the LED 3 comprises the surface electrode 32 and the dielectric antenna 36, it is possible to produce a large amount of light intensity and to bring the generated light to outside with high efficiency.

As a result, since it is possible not only to secure a light intensity necessary for a general illumination device but also to reduce generation of heat because of high efficiency, any heat dissipating member is not required.

Furthermore, the resin having a small heat resistance can be used for the diffusion member 2 or the light diffraction sheet 4 because the heat generation is restrained, which makes it possible to enlarge selectivity of a shape or a material of the diffusion member 2 or the light diffraction sheet 4, thereby enabling preferable lighting for various purposes.

In addition, since it is possible to produce the light dispersing action just by attaching the light diffraction sheet 4 to the diffusion member 2, no burden will be imposed on a manufacturing process.

The present claimed invention is not limited to the above-mentioned embodiment. The same parts as those in the first embodiment are denoted by the same reference numerals as those in the embodiment. For example, the light diffraction sheet 4 may be a sheet on which multiple slits or grids are carved or printed. Instead of the light diffraction sheet 4, an action of the diffraction member may be produced by carving micro-grids on a surface of the light diffusion member 2.

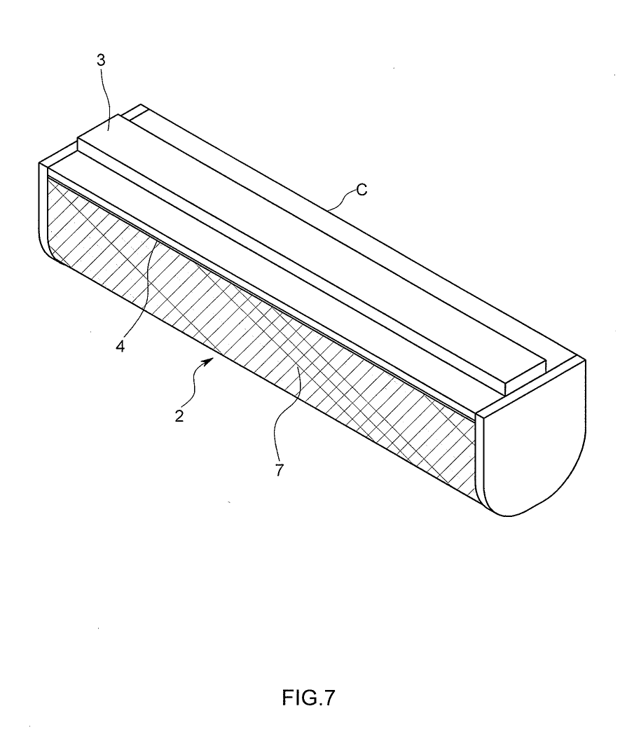

For example, the LED illumination device 1 shown in FIG. 7 is provided with the diffusion member 2 that has no groove and that is of a columnar shape whose cross-section is a generally half circle. Furthermore, the light diffraction sheet 4 is attached to a side surface located at a string side of the half circle as viewed in cross-section. A transparent mounting plate (C) is attached to the light diffraction sheet 4 and a straight belt shaped LED 3 is attached to the mounting plate (C) with its luminous surface facing the light diffraction sheet 4 and its longitudinal direction coincided with a longitudinal direction of the diffusion member 2. Furthermore, a side surface to which no light diffraction sheet 4 is attached is made to be in a frosted glass state by arranging micro concaves and convexes 7 by means of a sandblasting process. In this embodiment, the inside of the diffusion member 2 does not contain the light scattering particle 21, however, both the micro concaves and convexes 7 and the light scattering particles 21 may be used.

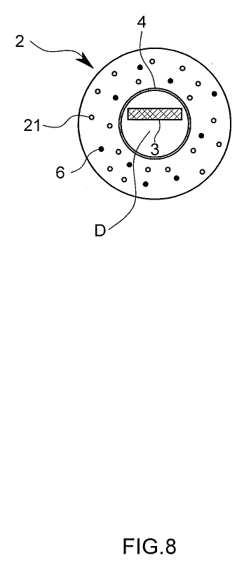

In addition, as shown in FIG. 8, a through bore (D) may be formed at a center of the diffusion member 2, the light diffraction sheet 4 may be attached to an inner surface of the through bore (D) and the LED 3 may be arranged at the center of the diffusion member 2. Not only the light scattering particles 21 but also a fluorescent material 6 may be mixed inside of the diffusion member 2.

In accordance with this arrangement, the ultraviolet light or the blue light from the LED 3 is dispersed into the multiple point light sources or the line light source by the light diffraction sheet 4. A part of the dispersed light produces fluorescence on the fluorescent material 6 and then irradiates outside from the diffusion member 2 while being scattered by the light scattering particles 21. Other light goes out from the diffusion member 2 without producing fluorescence on the fluorescent material 6 and then is mixed with the fluorescent light. As mentioned, it is possible to increase a variation of luminescent colors.

In addition, the fluorescent material may be applied to a surface of the diffusion member. Furthermore, the LED is not limited to a single LED and may be a line comprising multiple LEDs. The LED may be an LED without using a dielectric antenna.

The present claimed invention is not limited to the above-mentioned illustrated examples or embodiments and may be variously modified without departing from the spirit of the invention.

### POSSIBLE APPLICATIONS IN INDUSTRY

In accordance with this invention having the above arrangement, since the diffraction member is arranged between the LED and the diffusion member, it is possible to obtain more uniform light compared to a case where the light is diffused by the light diffusion material alone. In addition, in the case of obtaining the light having the same uniform degree, since it is possible for the LED illumination device having the light diffraction sheet to make the light diffusing degree at the light diffusion member small compared to the LED illumination device having the light diffusion member alone, a loss of luminous intensity at the light diffusion member can be reduced, thereby improving the efficiency as a whole.

Furthermore, since it is possible to conduct the ideal plane emission and to bring a large amount of the light intensity of the generated light to outside with high efficiency by making use of the dielectric antenna, it is possible not only to secure a light intensity necessary for a general illumination device but also to reduce the generation of heat because of the high efficiency. As a result, a resin having a small heat resistance can be used for the diffraction member or the diffusion member, a freedom degree in designing a shape or a material of the diffraction member or the diffusion member can be greatly enlarged, which makes it possible to provide the most appropriate illumination device appropriate for various purposes.

1. An LED illumination device comprising:
an LED equipped with a thin-plate-shaped semiconductor element body that transmits light generated in a PN junction area in a thickness direction and that emits the light from its surface, a surface electrode that is arranged to cover the surface of the semiconductor element body, and a plurality of columnar dielectric antennas that penetrate the surface electrode in a thickness direction and that condense the light transmitted in the semiconductor element body and emit it outside, a diffraction member that is arranged on a luminous surface side of the LED and that diffracts and disperses the light emitted by the LED, and
a diffusion member that is arranged outside the diffraction member and that diffuses the light dispersed by the diffraction member and emits it outside.

2. The LED illumination device described in claim 1, wherein the diffusion member is a lengthy member that is made of resin having translucency and that produces a light diffusing action inside or on its surface, and the LED is in a shape of a straight belt and is arranged next to the diffusion member or housed inside of the diffusion member with its longitudinal direction coincided with a longitudinal direction of the diffusion member.

3. The LED illumination device described in claim 1, wherein the diffraction member his a light transmission type diffraction sheet that diffracts and disperses the light while transmitting the light, and the light transmission type diffraction sheet his attached to a surface, which faces the luminous surface of the LED, of the diffusion member.

4. The LED illumination device described in claim 3, wherein the diffusion member his provided with a groove or a through bore extending toward a longitudinal direction and the LED his housed in the groove or the through bore, and the light transmission type diffraction sheet his attached to a portion facing the luminous surface of the LED as being a bottom surface of the groove or an inner surface of the through bore.

5. The LED illumination device described in claim 1, wherein the diffusion member is arranged so that light scattering particles are diffused inside of a body of the diffusion member made of a transparent resin.

6. The LED illumination device described in claim 1, wherein
the diffusion member has an arrangement wherein micro concavities and convexities are arranged on a surface of a body of the diffusion member made of a transparent resin.

7. The LED illumination device described in claim 1, wherein a fluorescent material his applied to a surface of the diffusion member or mixed into an inside of the diffusion member.
